(19) United States
(12) Patent Application Publication
(10) Pub. No.: US 2023/0178698 A1
(43) Pub. Date: Jun. 8, 2023

(54) DISPLAY DEVICE

(71) Applicant: KYOCERA CORPORATION, Kyoto-shi, Kyoto (JP)

(72) Inventors: Katsumi AOKI, Yasu-shi, Shiga (JP); Hiroaki ITO, Ritto-shi, Shiga (JP)

(21) Appl. No.: 17/920,007

(22) PCT Filed: Apr. 14, 2021
(86) PCT No.: PCT/JP2021/015450

§ 371 Date: Oct. 19, 2022

(30) Foreign Application Priority Data
Apr. 24, 2020 (JP) 2020-077809

(51) Int. Cl. H01L 33/62; H01L 25/075

(52) U.S. Cl. CPC H01L 33/62; H01L 25/0753

(57) ABSTRACT

A display device includes a substrate, a display, a first wiring pad, a first recess, a second wiring pad, and a side conductor. The substrate includes a first surface, a side surface, and a second surface opposite to the first surface. The display is located on the first surface and includes a pixel unit. The first wiring pad is located on the first surface in an edge area and is electrically connected with the pixel unit. The first recess is located on a first outer surface of the first wiring pad. The second wiring pad is located on the second surface at a position corresponding to the first wiring pad in an edge area. The side conductor extends from the first surface to the second surface through the side surface and connects the first wiring pad with the second wiring pad.

### TECHNICAL FIELD

The present disclosure relates to a display device.

### BACKGROUND OF INVENTION

A known display device is described in, for example, Patent Literature 1.

### CITATION LIST

### Patent Literature

Patent Literature 1: Japanese Unexamined Patent Application Publication No. 2018-141944

### SUMMARY

In an aspect of the present disclosure, a display device includes a substrate, a display, a first wiring pad, a first recess, a second wiring pad, and a side conductor. The substrate includes a first surface, a side surface, and a second surface opposite to the first surface. The display is located on the first surface and includes a pixel unit. The first wiring pad is located on the first surface in an edge area adjacent to one side of the first surface and is electrically connected with the pixel unit. The first recess is located on a first outer surface of the first wiring pad. The second wiring pad is located on the second surface at a position corresponding to the first wiring pad in the edge area adjacent to the one side. The side conductor extends from the first surface to the second surface through the side surface and connects the first wiring pad with the second wiring pad.

In another aspect of the present disclosure, a display device includes a substrate, a display, a power feeder, a plurality of first wiring pads, a plurality of second wiring pads, and a plurality of first side conductors. The substrate includes a first surface, a side surface, and a second surface opposite to the first surface. The display is located on the first surface and includes a plurality of gate signal lines, a plurality of source signal lines intersecting with the plurality of gate signal lines, and a plurality of pixel units arranged at intersections of the plurality of gate signal lines and the plurality of source signal lines. The power feeder is located on the second surface to generate a power supply voltage to be provided to the plurality of pixel units. The plurality of first wiring pads is located on the first surface in an edge area adjacent to a first side of the first surface and is connected with the plurality of pixel units. Each first wiring pad of the plurality of first wiring pads includes a plurality of first recesses on a first outer surface of the each first wiring pad opposite to a surface facing the first surface. The plurality of first recesses is arranged at first spacings in a direction parallel to the first side. The plurality of second wiring pads is located on the second surface and is connected with the power feeder. The plurality of first side conductors extends from the first surface to the second surface through the side surface and connects the plurality of first wiring pads with the plurality of second wiring pads.

### BRIEF DESCRIPTION OF THE DRAWINGS

The objects, features, and advantages of the present disclosure will become more apparent from the following detailed description and the drawings.

FIG. 1 is a schematic diagram of a display device according to one embodiment of the present disclosure illustrating circuit wiring and other components on a first surface.

FIG. 2 is a schematic diagram of the display device according to the embodiment of the present disclosure illustrating circuit wiring and other components on a second surface.

FIG. 3 is a schematic plan view of an example main part of the display device according to the embodiment of the present disclosure.

FIG. 4A is a cross-sectional view taken along line A1-A2 in FIG. 3.

FIG. 4B is a cross-sectional view taken along line B1-B2 in FIG. 3.

FIG. 5 is a schematic cross-sectional view of another example first wiring pad and another example third wiring pad in FIG. 4A.

FIG. 6 is a schematic plan view of another example main part of the display device according to the embodiment of the present disclosure.

FIG. 7A is a schematic plan view of another example main part of the display device according to the embodiment of the present disclosure.

FIG. 7B is a schematic plan view of another example main part of the display device according to the embodiment of the present disclosure.

FIG. 8A is a schematic plan view of another example main part of the display device according to the embodiment of the present disclosure.

FIG. 8B is a schematic plan view of another example main part of the display device according to the embodiment of the present disclosure.

FIG. 9 is a schematic plan view of another example main part of the display device according to the embodiment of the present disclosure.

FIG. 10 is a schematic plan view of another example main part of the display device according to the embodiment of the present disclosure.

FIG. 11A is a schematic plan view of another example main part of the display device according to the embodiment of the present disclosure.

FIG. 11B is a schematic plan view of another example main part of the display device according to the embodiment of the present disclosure.

FIG. 12A is a schematic plan view of another example main part of the display device according to the embodiment of the present disclosure.

FIG. 12B is a schematic plan view of another example main part of the display device according to the embodiment of the present disclosure.

FIG. 13A is a schematic plan view of another example main part of the display device according to the embodiment of the present disclosure.

FIG. 13B is a schematic plan view of another example main part of the display device according to the embodiment of the present disclosure.

FIG. 14A is a cross-sectional view taken along line C1-C2 in FIG. 12A.

FIG. 14B is a cross-sectional view of a display device according to another embodiment of the present disclosure corresponding to FIG. 14A.

FIG. 15 is a schematic plan view of another example main part of the display device according to the embodiment of the present disclosure.

### DESCRIPTION OF EMBODIMENTS

The structure that forms the basis of a display device according to one or more embodiments of the present disclosure will be described. A variety of display devices have been developed, including a display device including a display located on a first main surface of a substrate, and peripheral circuits such as a power supply circuit and a drive circuit located on a second main surface of the substrate opposite to the first main surface. A display device described in Patent Literature 1 includes a substrate with a first main surface and a second main surface, a first wiring pad located on the first main surface and connected with a display, a second wiring pad located on the second main surface and connected with peripheral circuits, and a side conductor extending from the first main surface to the second main surface through a side surface of the substrate and connecting the first wiring pad with the second wiring pad. In this display device, the side conductor may separate from the first wiring pad or the second wiring pad and cause wiring defects, defective image rendering, or other deterioration of image quality in an image displayed by the display device. The separation of the side conductor from the first wiring pad or the second wiring pad is to be reduced to improve the image quality of the display device.

The display device according to one or more embodiments of the present disclosure will now be described with reference to the drawings. Each figure referred to below illustrates main components and other elements of the display device according to one or more embodiments of the present disclosure. In the embodiments of the present disclosure, the display device may include known components that are not illustrated, for example, circuit boards, wiring conductors, control integrated circuits (ICs), and large-scale integration (LSI) circuits.

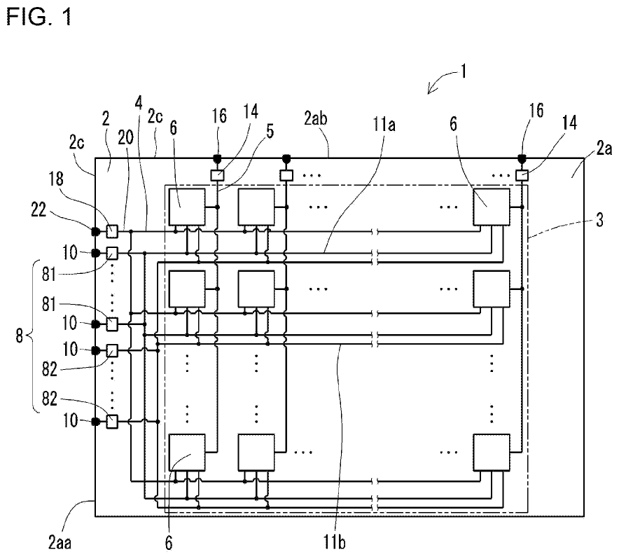

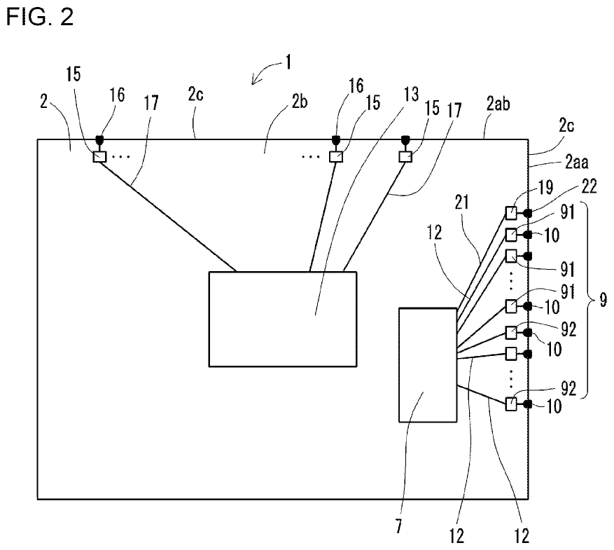

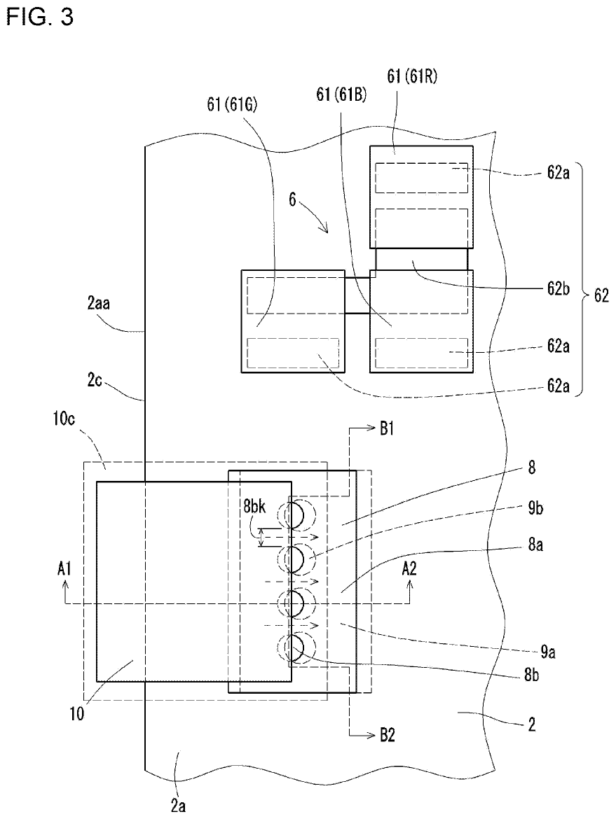

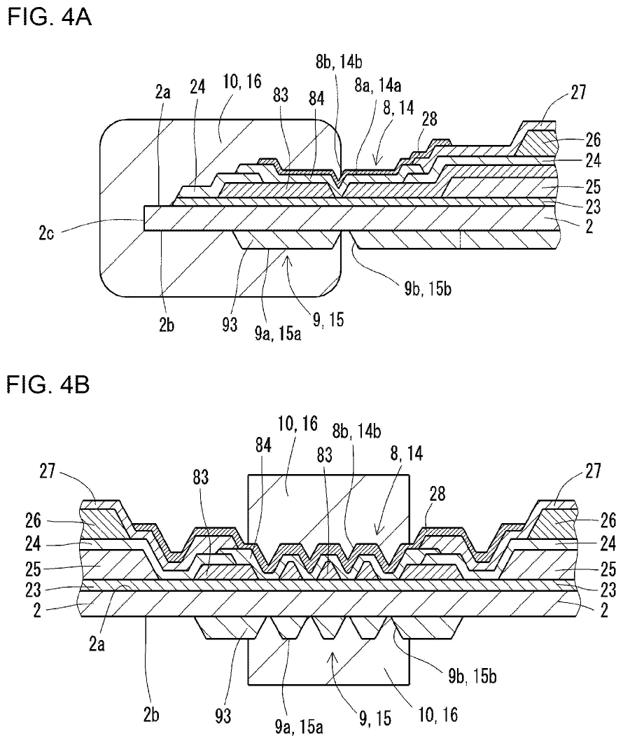

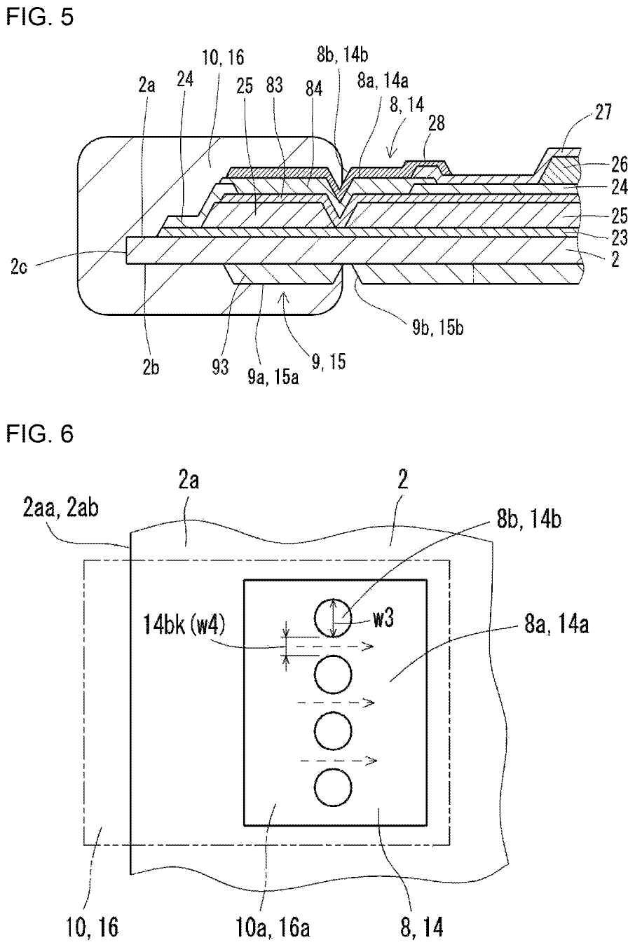

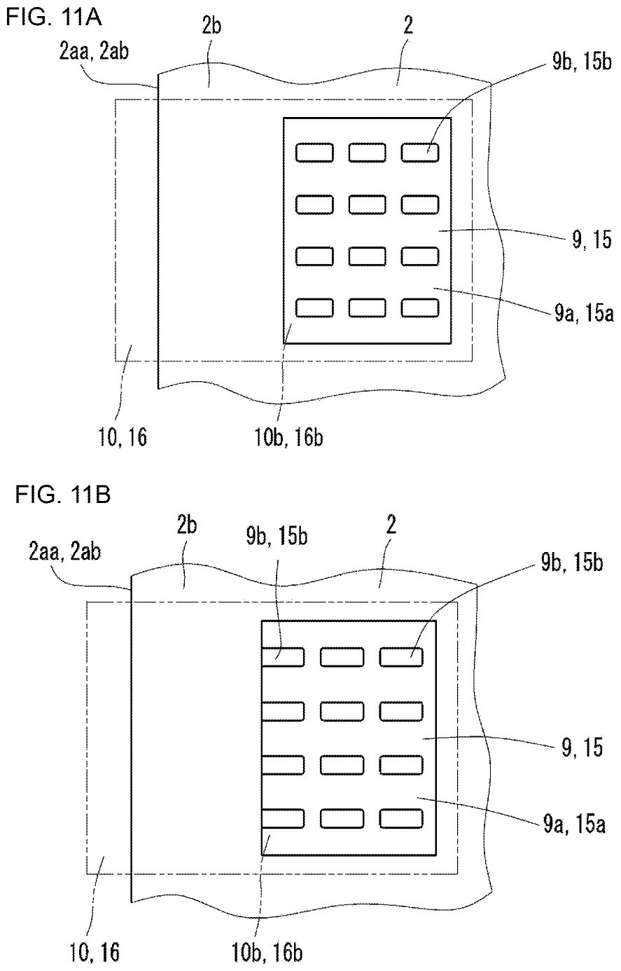

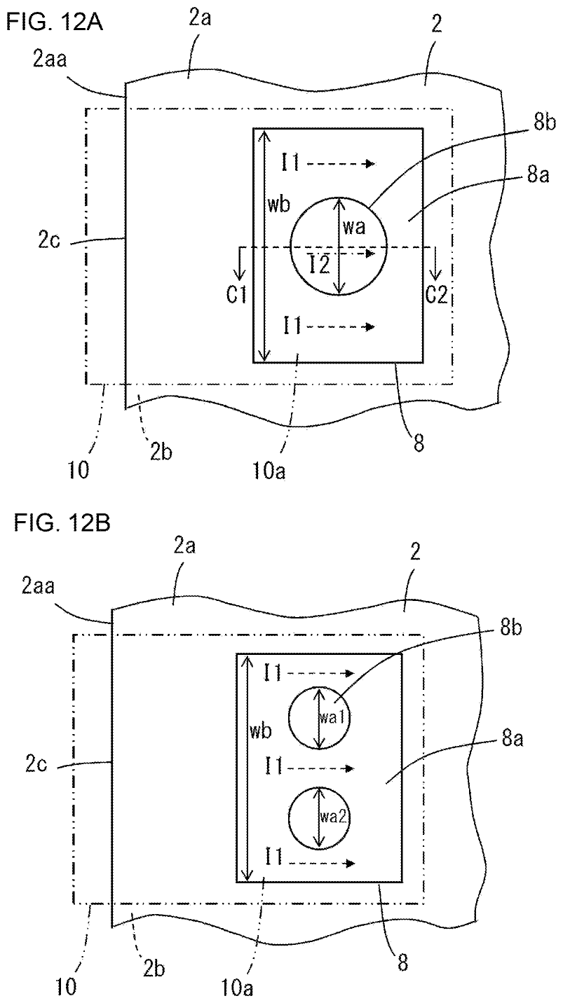

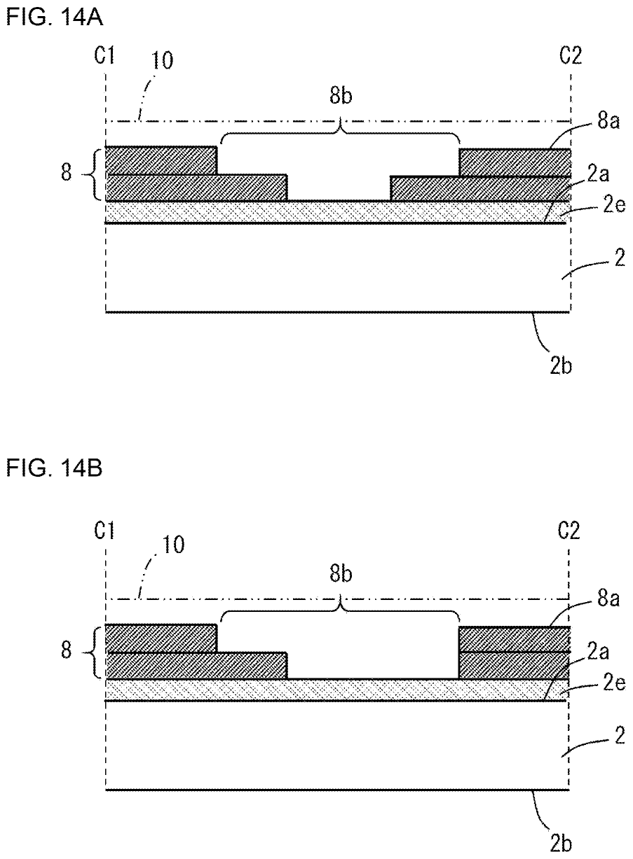

FIG. 1 is a schematic circuit diagram of a display device according to one embodiment of the present disclosure, illustrating circuit wiring and other components on a first surface of the display device. FIG. 2 is a schematic circuit diagram of the display device according to the embodiment of the present disclosure, illustrating circuit wiring and other components on a second surface of the display device. FIG. 3 is a schematic plan view of an example main part of the display device according to the embodiment of the present disclosure. For simplicity, FIG. 3 illustrates a pixel unit including light emitters, an electrode pad, a first wiring pad, and a second wiring pad without illustrating other elements. FIG. 4A is a cross-sectional view taken along line A1-A2 in FIG. 3. FIG. 4B is a cross-sectional view taken along line B1-B2 FIG. 3. FIG. 5 is a schematic cross-sectional view of another example first wiring pad and another example third wiring pad in FIG. 4A. FIGS. 6 to 13 and 15 each are a schematic plan view of another example main part of the display device according to the embodiment of the present disclosure. FIGS. 6 to 9, 12, 13, and 15 each schematically illustrate the structure including the first wiring pad and the third wiring pad located on the first surface. FIGS. 10 and 11 schematically illustrate the structure including the second wiring pad and a fourth wiring pad located on the second surface. FIG. 14A is a cross-sectional view taken along line C1-C2 in FIG. 12A. FIG. 14B is a cross-sectional view of a display device according to another embodiment of the present disclosure corresponding to FIG. 14A.

A display device 1 according to the present embodiment includes a substrate 2, a display 3, a power supply circuit 7, multiple first wiring pads 8, multiple second wiring pads 9, and multiple first side conductors 10.

As illustrated in FIGS. 1, 4A, and 12A, the display device 1 according to the present embodiment includes the substrate 2 including a first surface 2a, a side surface 2c, and a second surface 2b opposite to the first surface 2a, the display 3 on the first surface 2a including pixel units 6, the first wiring pads 8 located on the first surface 2a in an edge area adjacent to one side (first side 2aa) and electrically connected with the pixel units 6, first recesses 8b on first outer surfaces 8a of the first wiring pads 8, the second wiring pads 9 on the second surface 2b at positions corresponding to the first wiring pads 8 in the edge area adjacent to the first side 2aa, and the first side conductors 10 extending from the first surface 2a to the second surface 2b through the side surface 2c and connecting the first wiring pads 8 with the second wiring pads 9.

The display device 1 with the above structure produces the effects described below. With the first recesses 8b on the first outer surface 8a of each first wiring pad 8 connected with the corresponding first side conductor 10, the first side conductor 10 is anchored and firmly connected with the first wiring pad 8. This reduces the likelihood of separation of the first side conductor 10 from the first wiring pad 8, thus improving the image quality of the display device 1. This also allows portions of the first wiring pad 8 other than the first recesses 8b on the first outer surface 8a to serve as current paths I1 (indicated by a dashed arrow in FIG. 12A) on which a current can flow easily. Further, the first side conductor 10 with a relatively large volume and a relatively large thickness (e.g., about 0.1 to 5 μm) received in the first recess 8b can serve as another current path 12 (indicated by a dot-dash arrow in FIG. 12A) on which a current can flow easily. Such a first side conductor 10 is less likely to be disconnected at the step of the first recess 8b. This avoids an increase in connection resistance (contact resistance) in a first connection 10a between the first wiring pad 8 and the first side conductor 10.

The first recess 8b is, in other words, a recess or depression, and may have an area of 5 to 30% of the area of the first outer surface 8a of the first wiring pad 8 as viewed in plan. In other words, the first recess 8b is different from fine irregularities on the first outer surface 8a of the first wiring pad 8 formed through surface roughening. For structures with a roughened first outer surface 8a, the first outer surface 8a of the first wiring pad 8 is roughened with either a chemical or mechanical method such as etching or sandblasting. However, these methods use more time and labor and also involve higher manufacturing costs due to the use of equipment such as etching or sandblasting tools and surface protection of other portions using a protective layer or another protective material to avoid roughening the other portions. Further, fine irregularities are difficult to form uniformly on the first outer surface 8a of the first wiring pad 8. In the display device 1 according to the present embodiment, the first recesses 8b may be formed at a lower cost with the thin film formation method used in forming the first wiring pad 8. In structures including multiple first wiring pads 8 as well, the first recesses 8b can be formed with a uniform shape and a uniform depth in each of the first wiring pads 8.

Each first recess 8b as viewed in plan may be circular, rectangular, rounded-corner rectangular, elliptic, trapezoidal, groove-shaped (strip-shaped) or in any other shape. The first recess 8b may be a groove extending in a direction orthogonal to the first side 2aa. This allows the current paths I1 to have a sufficient size.

Each second wiring pad 9 may include second recesses 9b located on a second outer surface 9a, and each first side conductor 10 may cover the first outer surface 8a and the second outer surface 9a. This allows signals to be provided from the second surface 2b to the display 3 located on the first surface 2a of the substrate 2 through the first side conductor 10 with a smaller voltage drop. A signal feeder to provide signals to the display 3 may be located on the second surface 2b. The signal feeder may be a power feeder that provides a power supply voltage, or may be a drive that provides drive signals such as gate signals and source signals.

As illustrated in FIG. 12A, when one first recess 8b is located on the first outer surface 8a, the maximum width wa of the first recess 8b in a direction parallel to the first side 2aa may be less than or equal to a half of the maximum width wb of the first outer surface 8a in the direction parallel to the first side 2aa. This allows the current paths I1 to have a sufficient size. The maximum width wa may be greater than or equal to 1/10 of the maximum width wb. The current paths I1 are likely to be small with the maximum width wa exceeding a half of the maximum width wb. The maximum width wa being less than 1/10 of the maximum width wb is likely to cause the first recess 8b to anchor the first side conductor 10 less firmly, thus degrading the connection of the first side conductor 10 with the first wiring pad 8 and reducing the size of the current path 12. The structure in FIG. 12A may also be used for the second recess 9b.

As illustrated in FIG. 12B, when multiple first recesses 8b are on the first outer surface 8a, the total of the maximum widths wa1 and wa2 of the first recesses 8b in the direction parallel to the first side 2aa may be less than or equal to a half of the maximum width wb of the first outer surface 8a in the direction parallel to the first side 2aa. This allows the current paths I1 to have a sufficient size. The total of the maximum widths wa1 and wa2 may be greater than or equal to 1/10 of the maximum width wb. The current paths I1 are likely to be small with the total of the maximum widths wa1 and wa2 exceeding a half of the maximum width wb. The total of the maximum widths wa1 and wa2 being less than 1/10 of the maximum width wb is likely to cause the first recesses 8b to anchor the first side conductor 10 less firmly, thus degrading the connection of the first side conductor 10 with the first wiring pad 8 and reducing the size of the current path 12. The structure in FIG. 12B may also be used for the second recess 9b.

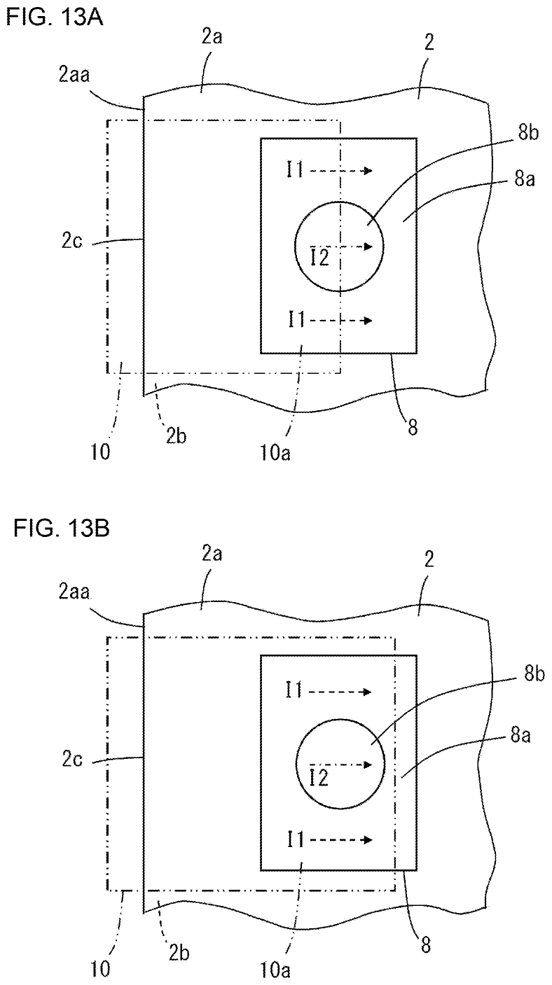

As illustrated in FIG. 13A, the first side conductor 10 may cover half or more of the area of the first outer surface 8a and half or more of the area of the first recess 8b. This allows a smaller-volume conductor to be used as the first side conductor 10, avoids an increase in connection resistance at a connection between the first wiring pad 8 and the first side conductor 10, and allows the first recess 8b to anchor the first side conductor 10 in a reliable manner. This also reduces the likelihood of unintended short-circuiting caused by the first side conductor 10 contacting, for example, another electrode or wiring. The structure in FIG. 13A may also be used for the second recess 9b.

As illustrated in FIG. 13B, the first side conductor 10 may cover more than half of the area of the first outer surface 8a and fully cover the first recess 8b. This allows a relatively smaller-volume conductor to be used as the first side conductor 10, avoids an increase further in connection resistance at the connection between the first wiring pad 8 and the first side conductor 10, and allows the first recess 8b to anchor the first side conductor 10 in a more reliable manner. This also reduces the likelihood of unintended short-circuiting caused by the first side conductor 10 contacting, for example, another electrode or wiring. The structure in FIG. 13B may also be used for the second recess 9b.

As illustrated in FIG. 14A, the first wiring pad 8 may have a multilayer structure with multiple metal layers (including one or more alloy layers) stacked on one another, with the maximum width of the first recess 8b gradually decreasing in the depth direction. This increases the number of steps in the first recess 8b, thus increasing the number of portions to hold the first side conductor 10 in the first recess 8b. This allows the first recess 8b to anchor the first side conductor 10 more firmly. In FIG. 14A, an insulating layer 2e is illustrated.

The structure in FIG. 14A may include more steps in the first recess 8b adjacent to the first side 2aa than at a position opposite to the first side 2aa, as illustrated in FIG. 14B. In this case, when the first side conductor 10 is formed by applying and firing a conductive paste, the first side conductor 10 decreases in volume during the process of firing the conductive paste and retracts slightly toward the first side 2aa. This allows the steps in the first recess 8b adjacent to the first side 2aa to hold the first side conductor 10 more easily than the steps in the first recess 8b at the position opposite to the first side 2aa. This allows the first recess 8b to anchor the first side conductor 10 in a reliable manner or more firmly.

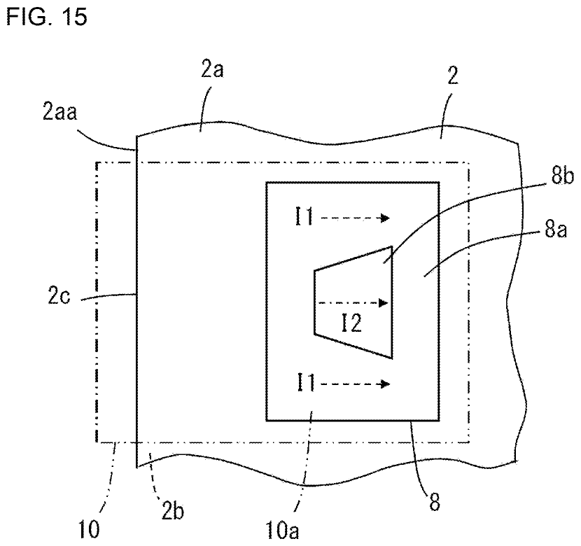

As illustrated in FIG. 15, the width of the first recess 8b adjacent to the first side 2aa in the direction parallel to the first side 2aa may be smaller than the width at the opposite position in the direction parallel to the first side 2aa. In this case, when the first side conductor 10 is formed by applying and firing a conductive paste, the first side conductor 10 decreases in volume during the process of firing the conductive paste and retracts slightly toward the first side 2aa. This structure then reduces the retraction of the conductive paste in the first recess 8b toward the first side 2aa. This reduces the likelihood of separation of the first side conductor 10 from a step at a position opposite to the first side 2aa in the first recess 8b. The first recess 8b is trapezoidal in FIG. 15 as viewed in plan, but the first recess 8b may be T-shaped, triangular, corner-rounded triangular, or in any other shape as viewed in plan. As in FIG. 12B, a single first wiring pad 8 may include multiple first recesses 8b.

The substrate 2 is, for example, a transparent or opaque glass substrate, a plastic substrate, or a ceramic substrate. The substrate 2 includes the first surface 2a, the second surface 2b opposite to the first surface 2a, and a third surface 2c (hereafter also referred to as the side surface) connecting the first surface 2a with the second surface 2b. The substrate 2 may be triangular, rectangular, hexagonal, or in any other shape. The substrate 2 being, for example, triangular, rectangular, or hexagonal, allows easy tiling of multiple display devices 1 to fabricate a composite large display device (hereafter also referred to as a multi-display). As illustrated in, for example, FIGS. 1 and 2, in the present embodiment, the substrate 2 is rectangular, and the first surface 2a has the first side 2aa and a second side 2ab continuous with the first side 2aa.

The display 3 is located on the first surface 2a of the substrate 2. The display 3 includes multiple gate signal lines 4, multiple source signal lines 5, and multiple pixel units 6. The gate signal lines 4 extend in a predetermined direction (e.g., in the lateral direction in FIG. 1). The source signal lines 5 intersect with the gate signal lines 4. The pixel units 6 are arranged at intersections of the gate signal lines 4 and the source signal lines 5. As illustrated in, for example, FIG. 1, the pixel units 6 are arranged in a matrix at a predetermined pixel pitch.

Each of the pixel units 6 includes a light emitter 61 and an electrode pad 62.

The light emitter 61 is, for example, a self-luminous light emitter such as a light-emitting diode (LED), an organic electroluminescent element, or a semiconductor laser element. In the present embodiment, the light emitter 61 is an LED. The light emitter 61 may also be a micro-LED. The light emitter 61 being a micro-LED, located on the first surface 2a, may be rectangular as viewed in plan with each side having a length of about 1 to 100 μm inclusive or about 3 to 10 μm inclusive.

The light emitter 61 includes an anode terminal and a cathode terminal. The electrode pad 62 includes an anode pad 62a and a cathode pad 62b. The anode terminal and the cathode terminal of the light emitter 61 are electrically connected with the anode pad 62a and the cathode pad 62b with a conductive bond, such as a conductive adhesive or solder.

Each pixel unit 6 may include multiple light emitters 61, multiple anode pads 62a, and multiple cathode pads 62b. The anode pads 62a are electrically connected with the anode terminals of the light emitters 61. The cathode pads 62b are electrically connected with the cathode terminals of the light emitters 61. The light emitters 61 may include a light emitter 61R that emits red light, a light emitter 61G that emits green light, and a light emitter 61B that emits blue light. In this case, each pixel unit 6 allows display of color gradients. Each pixel unit 6 may include, instead of the light emitter 61R that emits red light, a light emitter that emits orange, red-orange, red-violet, or violet light. Each pixel unit 6 may include, instead of the light emitter 61G that emits green light, a light emitter that emits yellow-green light.

As illustrated in, for example, FIG. 2, the power supply circuit 7 as the power feeder is located on the second surface 2b. The power supply circuit 7 generates a first power supply voltage VDD and a second power supply voltage VSS to be provided to the pixel units 6. The power supply circuit 7 includes a VDD terminal for outputting the first power supply voltage VDD and a VSS terminal for outputting the second power supply voltage VSS. The first power supply voltage VDD is an anode voltage of, for example, about 10 to 15 V. The second power supply voltage VSS is lower than the first power supply voltage VDD and is a cathode voltage of, for example, about 0 to 3 V. The power supply circuit 7 may be a flexible circuit board (FPC), for example. The power feeder may be a circuit module including a semiconductor device such as an IC or an LSI circuit for power supply voltage control. The power feeder may further include, in addition to the power supply circuit 7, a light emission controller including an IC chip to generate control signals to control the emission or non-emission state and the light intensity of the light emitters 61.

The first wiring pads 8 are located on the first surface 2a in the edge area adjacent to the first side 2aa of the first surface 2a as illustrated in, for example, FIG. 1. The edge area is a peripheral area along the first side 2aa with a width of about 10 to 500 μm from the first side 2aa of the first surface 2a toward the center of the first surface 2a. The edge area may have a width other than these values. The first wiring pads 8 include multiple first pads 81 and multiple second pads 82. The first pads 81 are used to provide the first power supply voltage VDD to the pixel units 6. The second pads 82 are used to provide the second power supply voltage VSS to the pixel units 6. The first wiring pads 8 may be rectangular and have each side with a length of 50 to 500 μm or 70 to 300 μm. The first wiring pads 8 may have sides with any length, and may be pentagonal or in other polygonal shapes, trapezoidal, circular, or elliptic, or in other various shapes. The wiring pads hereafter may have the same or similar structure as described above.

Each of the first wiring pads 8 includes the first outer surface 8a opposite to a surface facing the first surface 2a. As illustrated in, for example, FIG. 3, the multiple first recesses 8b are arranged on the first outer surface 8a at first spacings 8bk in the direction parallel to the first side 2aa. This allows the portions corresponding to the first spacings 8bk of the first wiring pad 8 to serve as current paths (indicated by dashed arrows in FIG. 3) on which a current can flow easily, thus avoiding an increase in electrical resistance of the first wiring pad 8. In other words, a current flows easily in the portions corresponding to the first spacings 8bk of the first wiring pad 8 due to a short creepage distance of the first wiring pad 8 including conductor layers and the constant thickness of the first wiring pad 8. Each first spacing 8bk is the spacing between two adjacent first recesses 8b.

In the display device 1 according to the present embodiment, each first spacing 8bk may be greater than the maximum width of each first recess 8b in the direction parallel to the first side 2aa. The first spacing 8bk of the first wiring pad 8 greater than the maximum width of the first recess 8b is the width of a portion serving as a current path on which a current can flow easily to avoid an increase in electrical resistance of the first wiring pad 8. For a first recess 8b having a constant width in the direction parallel to the first side 2aa, the maximum width may be simply defined as a width. When each first recess 8b has a maximum width w1 in the direction parallel to the first side 2aa and each first spacing 8bk has a width w2, the width w2 may be greater than the maximum width w1 and not greater than about 15 times the maximum width w1. The maximum width w1 may be about 0.1 to 30 μm, or about 0.3 to 10 μm. The depth of the first recess 8b formed on a metal layer 83 by photolithography or another processing method may be about 100 to 1000 nm. The depth of the first recess 8b formed on an insulating layer 25 by photolithography or another processing method may be about 1 to 5 μm. The recesses on a wiring pad hereafter may have the same or similar structure as described above.

Each first recess 8b may be formed by forming a primary recess first on at least one of the metal layer 83 (FIGS. 4A and 4B) or the insulating layer 25 (FIG. 5) in the first wiring pad 8 by, for example, photolithography or dry etching, and then stacking one or more other layers in the primary recess. The recesses on a wiring pad described hereafter may be formed with the same or similar method as described above. The insulating layer 25 may be made of an inorganic insulating material such as SiO₂ or Si₃N₄, for example, or an organic insulating material such as an acrylic resin or polycarbonate, for example.

As illustrated in, for example, FIG. 1, the display device 1 includes first routing wires 11a and second routing wires 11b. The first routing wires 11a and the second routing wires 11b are located on the first surface 2a. The first routing wires 11a and the second routing wires 11b include, for example, Mo/Al/Mo or MoNd/AlNd/MoNd. The stack of Mo/Al/Mo includes a Mo layer, an Al layer, and a Mo layer in this order. The same or similar structure applies to the others. The first routing wires 11a connect the anode terminals of the light emitters 61 with the first pads 81. The second routing wires 11b connect the cathode terminals of the light emitters 61 with multiple second pads 82.

The first routing wires 11a and the second routing wires 11b may be planar wiring patterns. The first routing wires 11a and the second routing wires 11b may be electrically insulated from each other with an insulating layer (not illustrated) between them. The first routing wires 11a may include the anode pads 62a of the electrode pads 62 as parts of the first routing wires 11a.

The second wiring pads 9 are located on the second surface 2b. The second wiring pads 9 may be located in the edge area adjacent to the first side 2aa as illustrated in, for example, FIG. 2. This edge area may be the same as or similar to the edge area described above. The second wiring pads 9 include multiple third pads 91 and multiple fourth pads 92. The third pads 91 are used to provide the first power supply voltage VDD to the pixel units 6. The fourth pads 92 are used to provide the second power supply voltage VSS to the pixel units 6.

The display device 1 includes as many first pads 81 as the third pads 91, and as many second pads 82 as the fourth pads 92. The first pads 81 may overlap the respective third pads 91 as viewed in plan, or in other words, as viewed in a direction orthogonal to the first surface 2a. The second pads 82 may overlap the respective fourth pads 92 as viewed in plan.

The display device 1 includes third routing wires 12. The third routing wires 12 are located on the second surface 2b. The third routing wires 12 include, for example, Mo/Al/Mo, MoNd/AlNd/MoNd, or Ag. As illustrated in, for example, FIG. 2, the third routing wires 12 connect the VDD terminal in the power supply circuit 7 with the third pads 91 and connects the VSS terminal in the power supply circuit 7 with the fourth pads 92.

The first side conductors 10 extend from the first surface 2a through the third surface 2c to the second surface 2b. In the present embodiment, as illustrated in, for example, FIGS. 4A, 4B, and 5, the first side conductors 10 extend from the first surface 2a to the third surface 2c and to the second surface 2b. The first side conductors 10 connect the first wiring pads 8 with the second wiring pads 9. The first side conductors 10 connect the first pads 81 with the third pads 91, and connect the second pads 82 with the fourth pads 92 as illustrated in, for example, FIGS. 1 and 2.

The display device 1 may include, instead of the first side conductors 10, multiple feed-through conductors extending through the substrate 2 from the first surface 2a to the second surface 2b and connecting the first wiring pads with the second wiring pads. The display device 1 may also include both multiple feed-through conductors and multiple first side conductors 10. In the present embodiment, the display device 1 may include at least multiple first side conductors 10.

The display device 1 includes gate wires extending from the first surface 2a to the second surface 2b and connecting the gate signal lines 4 with the controller in the power supply circuit 7. As illustrated in, for example, FIGS. 1 and 2, the gate wires include a fifth wiring pad 18, a sixth wiring pad 19, a first gate wire 20, a second gate wire 21, and a third gate wire 22.

The fifth wiring pad 18 is located on the first surface 2a in the edge area adjacent to the first side 2aa of the first surface 2a as illustrated in, for example, FIG. 1. The sixth wiring pad 19 is located on the second surface 2b in the edge area adjacent to the first side 2aa of the second surface 2b as illustrated in, for example, FIG. 2. The fifth wiring pad 18 may overlap the sixth wiring pad 19 as viewed in plan. As illustrated in, for example, FIG. 1, the first gate wire 20 is located on the first surface 2a and connects the gate signal line 4 with the fifth wiring pad 18. As illustrated in, for example, FIG. 2, the second gate wire 21 is located on the second surface 2b and connects the controller in the power supply circuit 7 with the sixth wiring pad 19. As illustrated in, for example, FIGS. 1 and 2, the third gate wire 22 extends from the first surface 2a to the third surface 2c and to the second surface 2b and connects the fifth wiring pad 18 with the sixth wiring pad 19.

The pixel units 6, the first wiring pads 8, the second wiring pads 9, and the first side conductors 10 will now be described in detail.

In the present embodiment, as illustrated in, for example, FIG. 3, each pixel unit 6 includes the light emitter 61R that emits red light, the light emitter 61G that emits green light, and the light emitter 61B that emits blue light. Each pixel unit 6 includes the electrode pad 62 including three anode pads 62a and a cathode pad 62b. The light emitters 61R, 61G, and 61B may be arranged in an L shape as viewed in plan as illustrated in, for example, FIG. 3. This allows each pixel unit 6 to be smaller as viewed in plan, and to be compact and square as viewed in plan. The display device 1 thus includes pixels with higher density, allowing high-quality image display.

The first wiring pads 8 and the second wiring pads 9 are made of a conductive material. The first wiring pads 8 and the second wiring pads 9 may each include a single metal layer, or multiple metal layers stacked on one another. The first wiring pads 8 and the second wiring pads 9 may each include, for example, Al, Al/Ti, Ti/Al/Ti, Mo, Mo/Al/Mo, MoNd/AlNd/MoNd, Cu, Cr, Ni, or Ag. In the example of FIGS. 4A and 4B, a first wiring pad 8 includes two metal layers 83 and 84 stacked on each other and located on an insulating layer 23 on the first surface 2a. The insulating layer 23 may be made of, for example, SiO₂, Si₃N₄, or a polymeric material such as an acrylic resin. In the example of FIGS. 4A and 4B, a second wiring pad 9 includes a single metal layer 93 located on the second surface 2b.

As illustrated in, for example, FIGS. 4A, 4B, and 5, the first wiring pad 8 including the two metal layers 83 and 84 stacked on each other may include an insulating layer 24 partly between the metal layers 83 and 84. The first wiring pad 8 may include insulating layers 25, 26 and 27 at its inward (right in FIG. 4A) end on the first surface 2a. This reduces the likelihood of short-circuiting between the first wiring pad 8 and a wiring conductor or another element located inward on the first surface 2a. The insulating layers 25, 26 and 27 are made of, for example, SiO₂, Si₃N₄, or a polymeric material such as an acrylic resin. The first outer surface 8a of the first wiring pad 8 may be coated with a transparent conductive layer 28 of, for example, indium tin oxide (ITO) or indium zinc oxide (IZO). The second wiring pad 9 may have its surface coated with a transparent conductive layer of, for example, ITO or IZO.

As illustrated in, for example, FIG. 5, the insulating layer 25 may extend outward (left in FIG. 5) on the first surface 2a to be located between the metal layer 83 and the insulating layer 23. The portion of the insulating layer 25 located between the metal layer 83 and the insulating layer 23 may be uneven.

As illustrated in, for example, FIGS. 4A, 4B, and 5, a first side conductor 10 extends from the first surface 2a to the third surface 2c and to the second surface 2b and connects the corresponding first wiring pad 8 with the corresponding second wiring pad 9. The first side conductor 10 may include a conductive paste containing conductive particles of, for example, Ag, Cu, Al, or stainless steel, an uncured resin component, an alcohol solvent, and water. The conductive paste may be applied to an intended portion from the first surface 2a to the third surface 2c and to the second surface 2b and cured by heating, photocuring using ultraviolet ray irradiation, or a combination of photocuring and heating. The side conductor may also be formed with a thin film formation method such as plating, vapor deposition, or chemical vapor deposition (CVD). The third surface 2c may include a preformed groove in the portion to receive the first side conductor 10. This allows the conductive paste that forms the first side conductors 10 to be easily received in the intended portions on the third surface 2c.

In the present embodiment, the display device 1 includes multiple first recesses 8b on the first outer surface 8a of the first wiring pad 8 as illustrated in, for example, FIG. 3. This increases the area of contact between the first side conductor 10 and the first wiring pad 8 compared with a structure without the multiple first recesses 8b on the first outer surface 8a, either by allowing the first side conductor 10 to enter at least one of the first recesses 8b, or by allowing the first side conductor 10 to enter at least a portion of each of the first recesses 8b. This also anchors the first side conductor 10 onto the first wiring pad 8, either by allowing the first side conductor 10 to enter at least one of the first recesses 8b, or by allowing the first side conductor 10 to enter at least a portion of each of the first recesses 8b. This reduces the likelihood of separation of the first side conductor 10 from the first wiring pad 8, thus improving the image quality of the display device. The opening of each of the first recesses 8b may be, for example, a circular, rectangular, corner-rounded rectangular, elliptic, or in any other shape. The structure in FIG. 3 may include a protective insulating layer (overcoat) 10c covering the first side conductor 10. This anchors the protective insulating layer 10c also onto the first wiring pad 8 by allowing the protective insulating layer 10c to enter the portions of the first recesses 8b unreached by the first side conductor 10. This further reduces the likelihood of separation of the first side conductor 10 from the first wiring pad 8. The protective insulating layer 10c may be made of, for example, an acrylic resin or a polycarbonate resin.

As illustrated in, for example, FIG. 6, a first side conductor 10 connected with a first wiring pad 8 may fully cover the first outer surface 8a of the first wiring pad 8. The first side conductor 10 enters all the first recesses 8b to further increase the area of contact between the first side conductor 10 and the first wiring pad 8 and to anchor the first side conductor 10 onto the first wiring pad 8 more firmly. This further reduces the likelihood of separation of the first side conductor 10 from the first wiring pad 8, thus further improving the image quality of the display device.

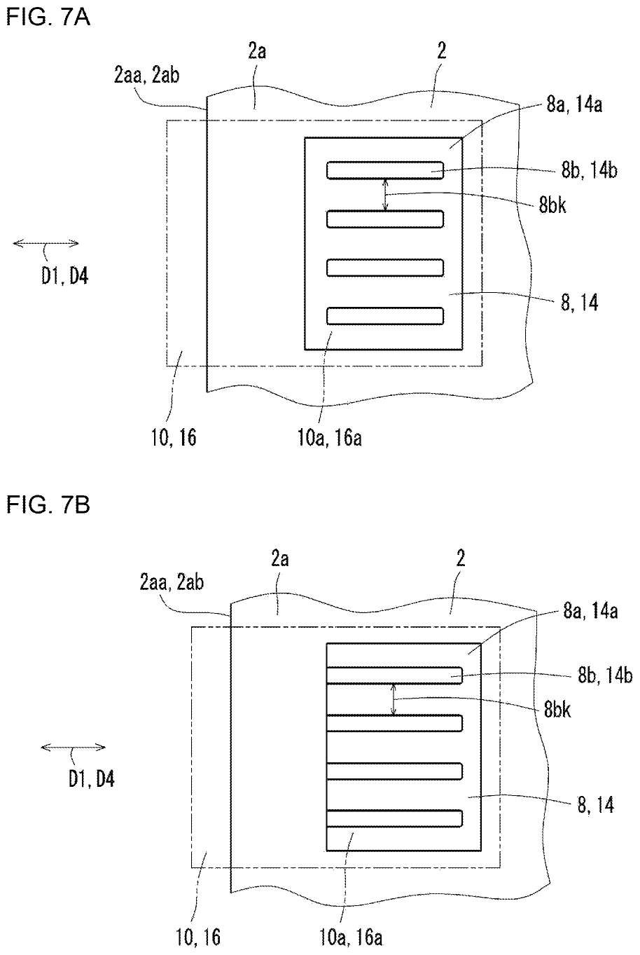

Each of the first recesses 8b as viewed in plan may be a groove elongated in a first direction D1, which is directed from the first side 2aa toward the center of the first surface 2a as illustrated in, for example, FIGS. 7A and 7B. This further increases the area of contact between the first side conductor 10 and the first wiring pad 8, thus reducing the contact resistance between the first side conductor 10 and the first wiring pad 8. The current paths in the first wiring pad 8 being less likely to have varying widths also maintain an easier flow of a current. The first recesses 8b being grooves may extend parallel to one another. In this case, current paths with no varying width can more reliably maintain an easier flow of a current. The length of each first recess 8b being a groove in the longitudinal direction may be slightly shorter (10 to 30% shorter) than the length of a side of the first wiring pad 8 (about 50 to 500 μm, or about 70 to 300 μm).

At least two of the first recesses 8b being grooves may extend parallel to each other. In other words, one or more of the first recesses 8b being grooves may not be parallel to the others, or all of the first recesses 8b may be parallel to one another. For example, of the first recesses 8b being grooves, grooves located in the central area may be parallel to a direction orthogonal to the first side 2aa, and grooves located at the two ends may not be parallel to the grooves in the central area, with the first spacing 8bk being smaller toward the first side 2aa. This substantially aligns the longitudinal directions of the first recesses 8b that are grooves with the direction in which the first side conductor 10 decreases in volume on the first wiring pad 8 in the process of firing, as viewed in plan, when the first side conductor 10 is formed by applying and firing a conductive paste. This reduces the likelihood of separation of the first side conductor 10 from the first wiring pad 8 due to lower adhesion between the first side conductor 10 and the first wiring pad 8. Of the first recesses 8b that are grooves, grooves located at the two ends may be inclined with respect to grooves located in the central area at an angle of about greater than 0° and not greater than 30°, or about not less than 5° and not greater than 20°.

The first direction D1 is a direction orthogonal to the first side 2aa as illustrated in, for example, FIGS. 7A and 7B. Each of the first recesses 8b may be a groove elongated in the first direction D1 as viewed in plan. In this case, at the first connection 10a of the first side conductor 10 located on the first outer surface 8a, the power supply current provided from the power supply circuit 7 flows substantially along the first surface 2a and in the direction orthogonal to the first side 2aa. Thus, when the first recesses 8b are grooves elongated in the first direction D1, the first connection 10a enters the first recesses 8b. This increases the cross-sectional area of the first connection 10a in the power supply current flow direction and reduces the electrical resistance of the first connection 10a. In other words, the first connection 10a in the first recesses 8b may serve as a current path with high conductivity. This reduces heat generation at the first connection 10a, thus reducing thermal stress at the interface between the first side conductor 10 and the first wiring pad 8. This further reduces the likelihood of separation of the first side conductor 10 from the first wiring pad 8, thus further improving the image quality of the display device. The first direction D1 is a direction orthogonal to the first side 2aa, and the first recesses 8b being grooves may extend parallel to one another. In this case, current paths in the first wiring pad 8 with no varying width more reliably maintain an easier flow of a current.

Each of the first recesses 8b may extend over substantially the full first outer surface 8a in the first direction D1. This effectively reduces electrical resistance of the first connection 10a. This effectively reduces heat generation at the first connection 10a, thus effectively reducing thermal stress at the interface between the first side conductor 10 and the first wiring pad 8. This further reduces the likelihood of separation of the first side conductor 10 from the first wiring pad 8, thus further improving the image quality of the display device.

As illustrated in FIG. 7B, at least one or more of the first recesses 8b may be open at an end adjacent to the first side 2aa. This allows the conductive paste that forms the first side conductors 10 to easily enter the first recesses 8b through the openings of the first recesses 8b. All the first recesses 8b may also be open at an end adjacent to the first side 2aa. The structure in FIG. 7B may also be used for third recesses 14b (described later).

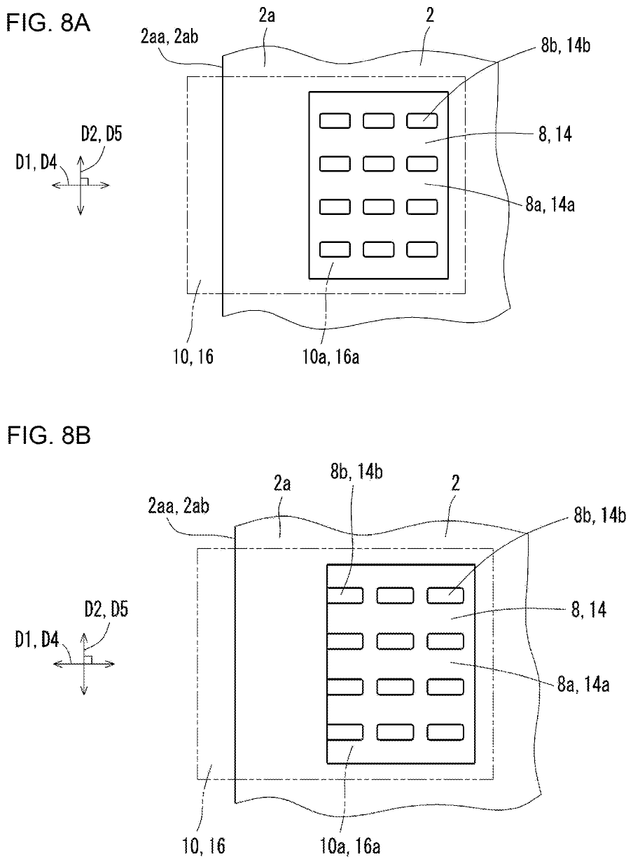

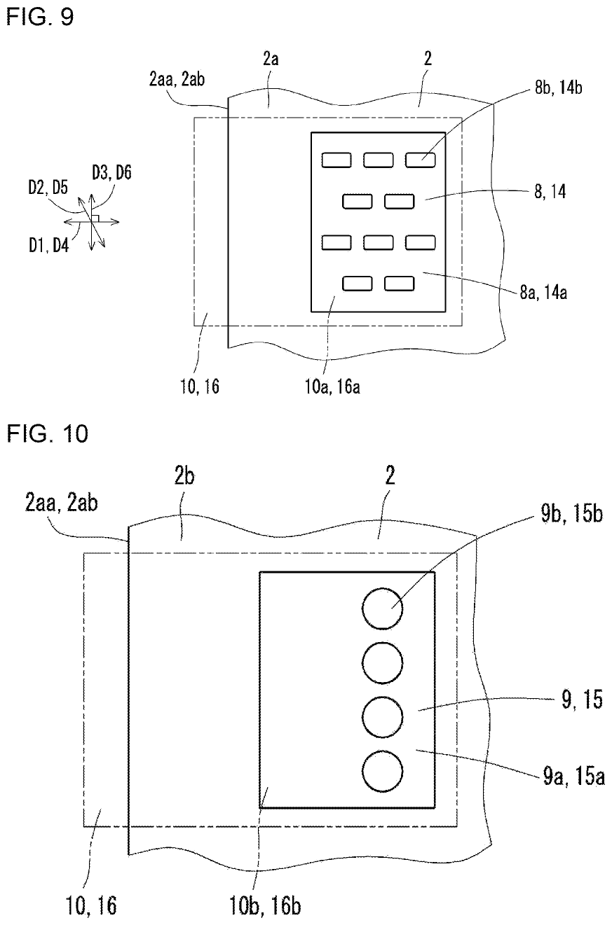

The first recesses 8b may be arranged in a matrix in the first direction D1 and in a second direction D2 intersecting with the first direction D1 as viewed in plan as illustrated in, for example, FIGS. 8A, 8B, and 9. The first direction D1 and the second direction D2 may have an angle of 90° between them as viewed in plan as illustrated in, for example, FIGS. 8A and 8B, or may have an angle greater than 0° and less than 90° between them as illustrated in, for example, FIG. 9. The first recesses 8b may be arranged in a matrix of multiple rows and columns.

As illustrated in FIG. 8B, of the first recesses 8b, recesses closest to the first side 2aa may be open at the end adjacent to the first side 2aa. This structure has the same or similar effects as the structure in FIG. 7B. The structure in FIG. 8B may also be used for the third recesses 14b (described later).

A matrix arrangement of the first recesses 8b allows more first recesses 8b to be located efficiently on the first outer surface 8a than a non-matrix arrangement of the first recesses 8b. This further increases the area of contact between the first side conductor 10 and the first wiring pad 8 and also anchors the first side conductor 10 onto the first wiring pad 8 more firmly. This also increases the cross-sectional area of the first connection 10a in the power supply current flow direction and reduces the electrical resistance of the first connection 10a. This effectively reduces heat generation at the first connection 10a and thus effectively reduces thermal stress at the interface between the first connection 10a and the first wiring pad 8, further reducing the likelihood of separation of the first side conductor 10 from the first wiring pad 8. This further improves the image quality of the display device.

As illustrated in, for example, FIG. 9, when the angle between the first direction D1 and the second direction D2 is greater than 0° and less than 90° as viewed in plan, or in other words, when the first recesses 8b are in a staggered arrangement as viewed in plan, the first recesses 8b are dispersed more on the first wiring pad 8 (more evenly distributed overall). This reduces local heat generation in the first side conductor 10, thus reducing the likelihood of a large thermal stress at the interface between the first wiring pad 8 and the first side conductor 10. This further reduces the likelihood of separation of the first side conductor 10 from the first wiring pad 8, thus further improving the image quality of the display device.

When the first recesses 8b are in a staggered arrangement as viewed in plan, the first recesses 8b are dispersed more overall on the first wiring pad 8, and may thus overlap one another with no gaps as viewed along the first surface 2a in a third direction D3 orthogonal to the first direction D1. This further increases the area of contact between the first side conductor 10 and the first wiring pad 8, thus reducing the contact resistance between the first side conductor 10 and the first wiring pad 8. This also further reduces the likelihood of separation of the first side conductor 10 from the first wiring pad 8, thus further improving the image quality of the display device.

As illustrated in, for example, FIG. 5, the insulating layer 25 located between the metal layer 83 and the insulating layer 23 may also allow the depth of the first recess 8b on the first outer surface 8a to be greater. This further increases the area of contact between the first side conductor 10 and the first wiring pad 8 and also anchors the first side conductor 10 onto the first wiring pad 8 more firmly. This further reduces the likelihood of separation of the first side conductor 10 from the first wiring pad 8, thus further improving the image quality of the display device.

Each of the second wiring pads 9 includes the second outer surface 9a opposite to a surface facing the second surface 2b. As illustrated in, for example, FIGS. 3, 4A, and 4B, multiple second recesses 9b may be located on the second outer surface 9a. This increases the area of contact between the first side conductor 10 and the second wiring pad 9 compared with a structure without the multiple second recesses 9b on the second outer surface 9a by allowing the first side conductor 10 to enter at least one of the second recesses 9b. This also anchors the first side conductor 10 onto the second wiring pad 9 by allowing the first side conductor 10 to enter at least one of the second recesses 9b. This reduces the likelihood of separation of the first side conductor 10 from the second wiring pad 9, thus improving the image quality of the display device. The opening of each of the second recesses 9b may be, for example, circular, rectangular, corner-rounded rectangular, elliptic, or in any other shape.

As illustrated in, for example, FIG. 10, the first side conductor 10 connected with the second wiring pad 9 may fully cover the second outer surface 9a of the second wiring pad 9. In this case, the first side conductor 10 enters all the second recesses 9b to further increase the area of contact between the first side conductor 10 and the second wiring pad 9 and also to anchor the first side conductor 10 onto the second wiring pad 9 more firmly. This further reduces the likelihood of separation of the first side conductor 10 from the second wiring pad 9, thus further improving the image quality of the display device.

When the second outer surface 9a is made of a material such as ITO or IZO and the first side conductor 10 is a cured conductive paste containing Ag, the adhesion between the first side conductor 10 and the second wiring pad 9 is likely to be low. In this case, the second recesses 9b arranged in a matrix as illustrated in FIG. 11A further increase the area of contact between the first side conductor 10 and the second wiring pad 9 and also anchor the first side conductor 10 onto the first wiring pad 8 more firmly. This further reduces the likelihood of separation of the first side conductor 10 from the second wiring pad 9, thus further improving the image quality of the display device.

As illustrated in FIG. 11B, of the second recesses 9b, recesses closest to the first side 2aa may be open at an end adjacent to the first side 2aa. This structure has the same or similar effects as the structure in FIG. 8B. The structure in FIG. 11B may also be used for a fourth recess 15b.

At a second connection 10b of the first side conductor 10 located on the second outer surface 9a, the power supply current supplied from the power supply circuit 7 flows substantially along the second surface 2b and in the direction orthogonal to the first side 2aa. Thus, the second recesses 9b arranged in a matrix increase the cross-sectional area of the second connection 10b in the power supply current flow direction and reduce the electrical resistance of the second connection 10b. This reduces heat generation at the second connection 10b, thus reducing thermal stress at the interface between the second connection 10b and the second wiring pad 9. This further reduces the likelihood of separation of the first side conductor 10 from the second wiring pad 9, thus further improving the image quality of the display device.

Other components of the display device 1 according to the present embodiment will now be described.

The display device 1 further includes a drive circuit 13 as a drive, multiple third wiring pads 14, multiple fourth wiring pads 15, and multiple second side conductors 16.

As illustrated in, for example, FIG. 2, the drive circuit 13 is located on the second surface 2b of a substrate 2. The drive circuit 13 generates image signals to be provided to the pixel units 6. The drive circuit 13 may be mounted on the second surface 2b with a mounting technique such as chip on film (COF). The drive may be a driver with a semiconductor integrated circuit such as an IC or an LSI circuit.

The third wiring pads 14 are located on the first surface 2a in an edge area adjacent to the second side 2ab of the first surface 2a as illustrated in, for example, FIG. 1. The third wiring pads 14 are used to provide image signals generated by the drive circuit 13 to the pixel units 6, and are electrically connected with the respective source signal lines 5.

The third wiring pads 14 may each include a single metal layer, or multiple metal layers stacked on one another. The materials and structure of the third wiring pads 14, which are the same as or similar to those of the first wiring pads 8, will not be described in detail.

Each of the third wiring pads 14 includes a third outer surface 14a opposite to a surface facing the first surface 2a. As illustrated in, for example, FIG. 6, the third recesses 14b are arranged on the third outer surface 14a in the direction parallel to the second side 2ab at second spacings 14bk. This allows the portions of the second spacings 14bk of the third wiring pad 14 to serve as current paths (indicated by dashed arrows in FIG. 6) on which a current can flow easily, thus avoiding an increase in electrical resistance of the third wiring pad 14. In other words, a current flows easily in the portions of the second spacings 14bk of the third wiring pad 14 due to a short creepage distance of the third wiring pad 14 including conductor layers and the constant thickness of the third wiring pad 14. Each second spacing 14bk is the spacing between adjacent third recesses 14b.

In the display device 1 according to the present embodiment, each second spacing 14bk may be greater than the maximum width of each third recess 14b in the direction parallel to the second side 2ab. The second spacing 14bk of the third wiring pad 14 greater than the maximum width of the third recess 14b is the width of a portion serving as a current path on which a current can flow easily to avoid an increase in electrical resistance of the third wiring pad 14. For a third recess 14b having a constant width in the direction parallel to the second side 2ab, the maximum width may be simply defined as a width. When each third recess 14b has a maximum width w3 in the direction parallel to the second side 2ab and each second spacing 14bk has a width w4, the width w4 may be greater than the maximum width w3 and not greater than about 15 times the maximum width w3.

In the display device 1 according to the present embodiment, the third recesses 14b may have various structures that are the same as or similar to the structure of the first recesses 8b described above.

The fourth wiring pads 15 are located on the second surface 2b. The fourth wiring pads 15 may be located in the edge area adjacent to the second side 2ab as viewed in plan as illustrated in, for example, FIG. 2. The materials and structure of the fourth wiring pads 15, which are the same as or similar to those of the second wiring pads 9, will not be described in detail.

The display device 1 includes as many third wiring pads 14 as the fourth wiring pads 15. The third wiring pads 14 may overlap the respective fourth wiring pads 15 as viewed in plan.

The display device 1 includes fourth routing wires 17 located on the second surface 2b. The fourth routing wires 17 include, for example, Mo/Al/Mo, MoNd/AlNd/MoNd, or Ag. As illustrated in, for example, FIG. 2, the fourth routing wires 17 connect the drive circuit 13 with the fourth wiring pads 15.

The second side conductors 16 extend from the first surface 2a to the second surface 2b. The second side conductors 16 connect the third wiring pads 14 with the fourth wiring pads 15.

The materials and structure of the second side conductors 16, which are the same as or similar to those of the first side conductors 10, will not be described in detail.

In the present embodiment, the display device 1 includes multiple third recesses 14b on the third outer surface 14a of each third wiring pad 14. This increases the area of contact between the second side conductor 16 and the third wiring pad 14 compared with a structure without the multiple third recesses 14b on the third outer surface 14a by allowing the second side conductor 16 to enter at least one of the third recesses 14b. The second side conductor 16 anchors onto the third wiring pad 14 by allowing the second side conductor 16 to enter at least one of the third recesses 14b. This reduces the likelihood of separation of the second side conductor 16 from the third wiring pad 14, thus improving the image quality of the display device. The opening of each of the third recesses 14b may be, for example, circular, rectangular, corner-rounded rectangular, elliptic, or in any other shape.

As illustrated in, for example, FIG. 6, the second side conductor 16 connected with the third wiring pad 14 may fully cover the third outer surface 14a. In this case, the second side conductor 16 enters all the third recesses 14b to further increase the area of contact between the second side conductor 16 and the third wiring pad 14 and also to anchor the second side conductor 16 onto the third wiring pad 14 more firmly. This further reduces the likelihood of separation of the second side conductor 16 from the third wiring pad 14, thus further improving the image quality of the display device.

Each of the third recesses 14b as viewed in plan may be a groove elongated in a fourth direction D4, which is directed from the second side 2ab toward the center of the first surface 2a as illustrated in, for example, FIGS. 7A and 7B. At least two of the third recesses 14b being grooves may extend parallel to each other, similarly to the first recesses 8b. In other words, one or more of the third recesses 14b being grooves may not be parallel to the others, or all of the third recesses 14b may be parallel to one another.

The fourth direction D4 is a direction orthogonal to the second side 2ab, as illustrated in, for example, FIGS. 7A and 7B. Each of the third recesses 14b as viewed in plan may be a groove elongated in the fourth direction D4. In this case, at a third connection 16a of the second side conductor 16 located on the third outer surface 14a, the signal current supplied from the drive circuit 13 flows substantially along the first surface 2a and in the direction orthogonal to the second side 2ab. Thus, when the third recesses 14b are grooves elongated in the fourth direction D4, the third connection 16a enters the third recesses 14b. This increases the cross-sectional area of the third connection 16a in the signal current flow direction and reduces the electrical resistance of the third connection 16a. In other words, the third connection 16a in the third recesses 14b may serve as a current path with high conductivity. This reduces heat generation at the third connection 16a, thus reducing thermal stress at the interface between the second side conductor 16 and the third wiring pad 14. This further reduces the likelihood of separation of the second side conductor 16 from the third wiring pad 14, thus further improving the image quality of the display device. The fourth direction D4 is a direction orthogonal to the second side 2ab. The third recesses 14b being grooves may extend parallel to one another. In this case, current paths in the third wiring pad 14 with no varying width more reliably maintain an easier flow of a current.

Each of the third recesses 14b may extend over substantially the full third outer surface 14a in the fourth direction D4. This effectively reduces electrical resistance of the third connection 16a. This effectively reduces heat generation at the third connection 16a, thus effectively reducing thermal stress at the interface between the second side conductor 16 and the third wiring pad 14. This further reduces the likelihood of separation of the second side conductor 16 from the third wiring pad 14, thus further improving the image quality of the display device.

The third recesses 14b may be arranged in a matrix in the fourth direction D4 and in a fifth direction D5 intersecting with the fourth direction D4 as viewed in plan, as illustrated in, for example FIGS. 8A, 8B, and 9. The fourth direction D4 and the fifth direction D5 may have an angle of 90° between them as viewed in plan as illustrated in, for example, FIGS. 8A and 8B, or may have an angle greater than 0° and less than 90° between them as illustrated in, for example, FIG. 9. The third recesses 14b being grooves may be arranged in a matrix of multiple rows and columns.

A matrix arrangement of the third recesses 14b allows more third recesses 14b to be located efficiently on the third outer surface 14a than a non-matrix arrangement. This further increases the area of contact between the second side conductor 16 and the third wiring pad 14 and also anchors the second side conductor 16 onto the third wiring pad 14 more firmly. This also increases the cross-sectional area of the third connection 16a in the signal current flow direction and reduces the electrical resistance of the third connection 16a. This effectively reduces heat generation at the third connection 16a and thus effectively reduces thermal stress at the interface between the third connection 16a and the third wiring pad 14, further reducing the likelihood of separation of the second side conductor 16 from the third wiring pad 14. This further improves the image quality of the display device.

As illustrated in, for example, FIG. 9, when the angle between the fourth direction D4 and the fifth direction D5 is greater than 0° and less than 90° as viewed in plan, or in other words, when the third recesses 14b are in a staggered arrangement as viewed in plan, the third recesses 14b are dispersed more on the third wiring pad 14 (more evenly distributed overall). This reduces local heat generation in the second side conductor 16, thus reducing the likelihood of a large thermal stress at the interface between the third wiring pad 14 and the second side conductor 16. This further reduces the likelihood of separation of the second side conductor 16 from the third wiring pad 14, thus further improving the image quality of the display device.

When the third recesses 14b are in a staggered arrangement as viewed in plan, the third recesses 14b are dispersed more overall on the third wiring pad 14, and may thus overlap one another with no gaps as viewed along the first surface 2a in a sixth direction D6 orthogonal to the fourth direction D4. This further increases the area of contact between the second side conductor 16 and the third wiring pad 14, thus reducing the contact resistance between the second side conductor 16 and the third wiring pad 14. This further reduces the likelihood of separation of the second side conductor 16 from the third wiring pad 14, thus further improving the image quality of the display device.

As illustrated in, for example, FIG. 5, the insulating layer 25 located between the metal layer 83 and the insulating layer 23 may also allow the depth of the third recess 14b on the third outer surface 14a to be greater. This further increases the area of contact between the second side conductor 16 and the third wiring pad 14 and also anchors the second side conductor 16 onto the third wiring pad 14 more firmly. This further reduces the likelihood of separation of the second side conductor 16 from the third wiring pad 14, thus further improving the image quality of the display device.

Each of the fourth wiring pads 15 includes a fourth outer surface 15a opposite to a surface facing the second surface 2b. As illustrated in, for example, FIGS. 10, 11A, and 11B, multiple fourth recesses 15b may be located on the fourth outer surface 15a. This increases the area of contact between the second side conductor 16 and the fourth wiring pad 15 compared with a structure without the multiple fourth recesses 15b on the fourth outer surface 15a by allowing the second side conductor 16 to enter at least one of the fourth recesses 15b. This also anchors the second side conductor 16 onto the fourth wiring pad 15 by allowing the second side conductor 16 to enter at least one of the fourth recesses 15b. This reduces the likelihood of separation of the second side conductor 16 from the fourth wiring pad 15, thus improving the image quality of the display device. The opening of each of the fourth recesses 15b may be, for example, circular, rectangular, corner-rounded rectangular, elliptic, or in any other shape.

The second side conductor 16 connected with the fourth wiring pad 15 may fully cover the fourth outer surface 15a of the fourth wiring pad 15. In this case, the second side conductor 16 enters all the fourth recesses 15b to further increase the area of contact between the second side conductor 16 and the fourth wiring pad 15 and also to anchor the second side conductor 16 onto the fourth wiring pad 15 more firmly. This further reduces the likelihood of separation of the second side conductor 16 from the fourth wiring pad 15, thus further improving the image quality of the display device.

When the fourth outer surface 15a is made of a material such as ITO or IZO and the second side conductor 16 is a cured conductive paste containing Ag, the adhesion between the second side conductor 16 and the fourth wiring pad 15 is likely to be low. In this case, the fourth recesses 15b arranged in a matrix, as illustrated in, for example, FIGS. 11A and 11B, increase the area of contact between the second side conductor 16 and the fourth wiring pad 15 and also anchor the second side conductor 16 onto the fourth wiring pad 15 more firmly. This reduces the likelihood of separation of the second side conductor 16 from the fourth wiring pad 15, thus further improving the image quality of the display device.

At a fourth connection 16b of the second side conductor 16 located on the fourth outer surface 15a, the signal current supplied from the drive circuit 13 flows substantially along the second surface 2b and in the direction orthogonal to the second side 2ab. Thus, as illustrated in FIG. 11A, the fourth recesses 15b arranged in a matrix increase the cross-sectional area of the fourth connection 16b in the signal current flow direction and reduce the electrical resistance of the fourth connection 16b. This reduces heat generation at the fourth connection 16b, thus reducing thermal stress at the interface between the fourth connection 16b and the fourth wiring pad 15. This further reduces the likelihood of separation of the second side conductor 16 from the fourth wiring pad 15, thus further improving the image quality of the display device.

In the display device according to one or more embodiments of the present disclosure, the side conductor is anchored and firmly connected with the first wiring pad with the first recesses on the first outer surface of the first wiring pad connected with the side conductor. This reduces the likelihood of separation of the side conductor from the first wiring pad, thus improving the image quality of the display device. The portions of the first wiring pad other than the first recesses on the first outer surface serve as current paths on which a current can flow easily. When the portion of the side conductor received in the first recess has a relatively large volume and thickness, the side conductor in the first recess also serves as a current path on which a current can flow easily. This avoids an increase in connection resistance (contact resistance) at the connection between the first wiring pad and the side conductor.

In the display device according to one or more embodiments of the present disclosure, the first side conductor is anchored and firmly connected with the first wiring pad with the multiple first recesses on the first outer surface of the first wiring pad connected with the first side conductor. This reduces the likelihood of separation of the first side conductor from the first wiring pad, thus improving the image quality of the display device. The first recesses are arranged on the first outer surface of the first wiring pads at first spacings in the direction parallel to the first side. The first recesses further allow the portions of the first spacings of the first wiring pad to serve as current paths on which a current can flow easily. This avoids an increase in the electrical resistance of the first wiring pad.

Although embodiments of the present disclosure have been described in detail, the present disclosure is not limited to the embodiments described above, and may be changed or varied in various manners without departing from the spirit and scope of the present disclosure. The components described in the above embodiments may be fully or partially combined as appropriate unless any contradiction arises. For example, the fifth wiring pad 18 and the sixth wiring pad 19 for a gate wire may have the same or similar structure as the first wiring pad 8 and the second wiring pad 9, and the third gate wire 22 may have the same or similar structure as the first side conductor 10. This reduces the likelihood of separation of the third gate wire 22 from the fifth wiring pad 18 and the sixth wiring pad 19, thus improving the image quality of the display device.

### INDUSTRIAL APPLICABILITY

The display device according to one or more embodiments of the present disclosure can be used in various electronic devices. Such electronic devices include, for example, composite and large display devices (multi-displays), automobile route guidance systems (car navigation systems), ship route guidance systems, aircraft route guidance systems, smartphones, mobile phones, tablets, personal digital assistants (PDAs), video cameras, digital still cameras, electronic organizers, electronic dictionaries, personal computers, copiers, terminals for game devices, television sets, product display tags, price display tags, programmable display devices for commercial use, car audio systems, digital audio players, facsimile machines, printers, automatic teller machines (ATMs), vending machines, digital display watches, smartwatches, and information displays at stations, airports, and other facilities.

### REFERENCE SIGNS

1 display device
2 substrate
2a first surface
2aa first side
2ab second side
2b second surface
2c third surface
2e insulating layer
3 display
4 gate signal line
5 source signal line
6 pixel unit
61, 61R, 61G, 61B light emitter
62 electrode pad
62a anode pad
62b cathode pad
7 power supply circuit
8 first wiring pad
8a first outer surface
8b first recess
8bk first spacing
81 metal layer
81 first pad
82 second pad
83, 84 metal layer
9 second wiring pad
9a second outer surface
9b second recess
91 third pad
92 fourth pad
93 metal layer
10 first side conductor
10a first connection
10b second connection
10c protective insulating layer
11a first routing wire
11b second routing wire
12 third routing wire
13 drive circuit
14 third wiring pad
14a third outer surface
14b third recess
14bk second spacing
15 fourth wiring pad
15a fourth outer surface
15b fourth recess
16 second side conductor
16a third connection
16b fourth connection
17 fourth routing wire
18 fifth wiring pad
19 sixth wiring pad
20 first gate wire
21 second gate wire
22 third gate wire

1. A display device, comprising:
a substrate including a first surface, a side surface, and a second surface opposite to the first surface;
a display on the first surface, the display including a pixel unit;
a first wiring pad on the first surface in an edge area adjacent to one side of the first surface, the first wiring pad being electrically connected with the pixel unit;
a first recess on a first outer surface of the first wiring pad;
a second wiring pad on the second surface at a position corresponding to the first wiring pad in the edge area adjacent to the one side; and
a side conductor extending from the first surface to the second surface through the side surface and connecting the first wiring pad with the second wiring pad.

2. The display device according to claim 1, wherein
the second wiring pad includes a second recess on a second outer surface of the second wiring pad, and
the side conductor covers the first outer surface and the second outer surface.

3. The display device according to claim 1, wherein
when the first recess on the first outer surface is a single first recess, the single first recess has, in a direction parallel to the one side, a maximum width less than or equal to a half of a maximum width of the first outer surface in the direction parallel to the one side, and
when the first recess on the first outer surface is a plurality of the first recesses, a total of maximum widths of the plurality of the first recesses is, in the direction parallel to the one side, less than or equal to the half of the maximum width of the first outer surface in the direction parallel to the one side.

4. The display device according to claim 2, wherein
when the second recess on the second outer surface is a single second recess, the single second recess has, in a direction parallel to the one side, a maximum width less than or equal to a half of a maximum width of the second outer surface in the direction parallel to the one side, and
when the second recess on the second outer surface is a plurality of the second recesses, a total of maximum widths of the plurality of the second recesses is, in the direction parallel to the one side, less than or equal to the half of the maximum width of the second outer surface in the direction parallel to the one side.

5. A display device, comprising:
a substrate including a first surface, a side surface, and a second surface opposite to the first surface;
a display on the first surface, the display including a plurality of gate signal lines, a plurality of source signal lines intersecting with the plurality of gate signal lines, and a plurality of pixel units arranged at intersections of the plurality of gate signal lines and the plurality of source signal lines;
a power feeder on the second surface to generate a power supply voltage to be provided to the plurality of pixel units;
a plurality of first wiring pads on the first surface in an edge area adjacent to a first side of the first surface, the plurality of first wiring pads being connected with the plurality of pixel units, each first wiring pad of the plurality of first wiring pads including a plurality of first recesses on a first outer surface of the each first wiring pad, the plurality of first recesses being arranged at first spacings in a direction parallel to the first side;
a plurality of second wiring pads on the second surface, the plurality of second wiring pads being connected with the power feeder; and
a plurality of first side conductors extending from the first surface to the second surface through the side surface and connecting the plurality of first wiring pads with the plurality of second wiring pads.

6. The display device according to claim 5, wherein
each first spacing of the first spacings is greater than a maximum width of each first recess of the plurality of first recesses in the direction parallel to the first side.

7. The display device according to claim 5, wherein
each first recess of the plurality of first recesses is a groove elongated in a first direction from the first side toward a center of the first surface in a plan view of the first surface.

8. The display device according to claim 7, wherein
the first direction is orthogonal to the first side, and
the plurality of first recesses extends parallel to one another.

9. The display device according to claim 5, wherein
the plurality of first recesses is arranged in a matrix in the first direction and a second direction intersecting with the first direction in a plan view of the first surface.

10. The display device according to claim 5, wherein
each first side conductor of the plurality of first side conductors fully covers the first outer surface of a corresponding first wiring pad of the plurality of first wiring pads.

11. The display device according to claim 5, wherein
each second wiring pad of the plurality of second wiring pads includes a plurality of second recesses on a second outer surface of the each second wiring pad.

12. The display device according to claim 11, wherein
each first side conductor of the plurality of first side conductors fully covers the second outer surface of a corresponding second wiring pad of the plurality of second wiring pads.

13. The display device according to claim 5, further comprising:
a drive on the second surface to generate image signals to be provided to the plurality of pixel units;
a plurality of third wiring pads on the first surface in an edge area adjacent to a second side of the first surface adjoining the first side, the plurality of third wiring pads being electrically connected with the plurality of source signal lines, each third wiring pad of the plurality of third wiring pads including a plurality of third recesses on a third outer surface of the each third wiring pad, the plurality of third recesses being located at second spacings in a direction parallel to the second side;
a plurality of fourth wiring pads on the second surface, the plurality of fourth wiring pads being connected with the drive; and
a plurality of second side conductors extending from the first surface to the second surface through the side surface and connecting the plurality of third wiring pads with the plurality of fourth wiring pads.

14. The display device according to claim 13, wherein
each second spacing of the second spacings is greater than a maximum width of each third recess of the plurality of third recesses in the direction parallel to the second side.

15. The display device according to claim 13, wherein
the each third recess of the plurality of third recesses is a groove elongated in a third direction from the second side toward a center of the first surface in a plan view of the first surface.

16. The display device according to claim 15, wherein
the third direction is orthogonal to the second side, and
the plurality of third recesses extends parallel to one another.

17. The display device according to claim 13, wherein
the plurality of third recesses is arranged in a matrix in the third direction and a fourth direction intersecting with the third direction in a plan view of the first surface.

18. The display device according to claim 13, wherein
each second side conductor of the plurality of second side conductors fully covers the third outer surface of a corresponding third wiring pad of the plurality of third wiring pads.

19. The display device according to claim 13, wherein
each fourth wiring pad of the plurality of fourth wiring pads includes a plurality of fourth recesses on a fourth outer surface of the each fourth wiring pad.

20. The display device according to claim 19, wherein
each second side conductor of the plurality of second side conductors fully covers the fourth outer surface of a corresponding fourth wiring pad of the plurality of fourth wiring pads.
